(19) United States
(12) Patent Application Publication
(10) Pub. No.: US 2022/0404923 A1
(43) Pub. Date: Dec. 22, 2022

(54) Transportation Apparatus and Device and Method for the Operation of an Operating-Force-Sensitive Input Device of a Transportation Apparatus

(71) Applicant: Bayerische Motoren Werke Aktiengesellschaft, Muenchen (DE)

(72) Inventors: Thomas HILGER, Iffeldorf (DE); Boris ISRAEL, Muenchen (DE); Desiree MEYER, Muenchen (DE); Wolfgang Spiessl, Muenchen (DE)

(21) Appl. No.: 17/778,465

(22) PCT Filed: Nov. 4, 2020
(86) PCT No.: PCT/DE2020/100940

§ 371 Date: May 20, 2022

(30) Foreign Application Priority Data
Nov. 22, 2019 (DE) 10 2019 131 683.9

(51) Int. Cl. G06F 3/041; G06F 3/0488; G06F 3/0482

(52) U.S. Cl. CPC G06F 3/041; G06F 3/0488; G06F 3/0482; G06F 2203/04105

(57) ABSTRACT

A method includes automatically determining a first user input with a first predefined manipulation force acting on the input device and, in response thereto, performing a first function according to the first manipulation force. The method also includes automatically determining a second user input with a second predefined manipulation force acting on the input device, which second manipulation force is higher than the first manipulation force, and, in response thereto, selecting a first display element from a plurality of display elements displayed on a display unit, by switching an input focus to the first display element.

### BACKGROUND AND SUMMARY OF THE INVENTION

The present invention relates to a device, a transportation apparatus and a method for operating an operating-force-sensitive input device of a transportation apparatus.

Touchscreens (touch-sensitive screens) or pushbutton switches in conjunction with a display screen are widely used for operating increasingly numerous control functions, for example driver assistance systems (ADAS) and infotainment systems (IVIS), in vehicles in the prior art. Operation of the driver assistance and infotainment systems is often implemented by way of keys (operating elements) installed on the steering wheel, the function of which keys is often denoted by icons. The number of selectable functions (ADAS and IVIS) is high, resulting in a high level of complexity. This complexity is widely tackled by assigning the functions to main function groups, which are displayed in a menu. At present, at least two, often far more than two, keys (operating elements) are implemented for maneuvering through the menu and selecting a specific task. The keys are also implemented in the prior art as touch-sensitive surfaces that each have the same associated functions as keys.

DE 10 2016 007 024 A1 discloses a steering wheel for a motor vehicle, having a first and a second operating element, the complexity of the adjustment options being tackled by virtue of a first operating element with a first display displaying a main function alternative and being complemented by a second operating element with a second display, on which subfunction alternatives are displayed.

Moreover, touchscreens that may be controlled by way of so-called 3D Touch technology (Force Touch) have been used for portable electronic user terminals for a few years in the prior art. This involves a predefined function being triggered when a predefined force threshold acting on the touch-sensitive surface is reached, or after a predefined length of push. 3D Touch and Haptic Touch are functions of various products, in particular iPhone, from the manufacturer Apple. In the case of the 3D Touch function on the iPhone 6S, for example, two further actions linked with specific functions are detected in addition to the known input on the display: holding a push opens a preview and pushing harder activates a function. The latest Apple devices employ so-called Haptic Touch technology, wherein pushing for longer activates a function and acknowledges the activation by way of a vibration. 3D Touch technology has not been used in transportation apparatus to date.

Proceeding from the aforementioned prior art, it is an object of the present invention to reduce the complexity of the operating elements of a transportation apparatus. The aim of reducing the complexity is to distract the driver from the driving task to a lesser extent during a journey and therefore to increase the safety of vehicle driving.

The aforementioned object is achieved according to the invention by a method for operating an operating-force-sensitive input device of a transportation apparatus. The transportation apparatus may be a passenger car, transporter, truck, aircraft and/or watercraft, for example.

In a first step, a first user input having a first predefined operating force acting on the operating-force-sensitive input device is determined. The operating-force-sensitive input device may be implemented as a touchpad and/or using a so-called smart material or responsive material. Additionally or alternatively, the operating-force-sensitive input device may be in the form of a touchscreen (operating-force-sensitive screen). The touchscreen may be in particular in resistive form. Additionally or alternatively, the touchscreen may be in surface capacitive form. Finally, the touchscreen may also be in projected capacitive form. The user may use a finger to operate the operating-force-sensitive input device. Alternatively or additionally, the user may use an item for operation. An item may be a touch pen (input stylus), for example. On the basis of the first operating force, a first function is automatically performed. In a further step, which does not necessarily have to take place in a predefined temporal context in relation to the first touch input, a second user input having a second predefined operating force acting on the input device is automatically determined, which second operating force is higher than the first operating force. In other words, the same operating-force-sensitive input device is operated using a force that is greater than the first operating force. In response to the determination of the second user input having a second predefined operating force, a first display element is selected from a plurality of display elements displayed on a display unit by changing an input focus to the first display element. If an input focus is associated with a display element, then said display element may receive an input. Only precisely one display element at a time may ever have the input focus. The current input focus may be represented visually. A visual representation of the input focus may be achieved by way of a cursor/pointer, for example. Additionally or alternatively, a visual representation of the input focus may be represented by highlighting a display element. Highlighting may be achieved in particular by representing a corona and/or a frame around the current display element. Additionally or alternatively, highlighting may be achieved by way of a particular font. Additionally or alternatively, highlighting may be achieved by way of a particular size of an object associated with the display element that differs from the size of the objects associated with the plurality of display elements. Finally, highlighting may be achieved by way of enlarged representation of the display element on which there is the current input focus compared to the size of the representation of the plurality of display elements on which there is accordingly no input focus. Additionally or alternatively, the current input focus may be transmitted to the user acoustically. The first display element may be predefined. Additionally or alternatively, the first display element may relate to a previous display. In other words, the first display element may be the display element displayed most recently when the operating-force-sensitive input device was used previously, for example. A change to a first display element may be made by changing the display position of a display element displayed in a display. Precisely one display element, preferably the one on which there is the input focus, may be displayed to the user. Additionally or alternatively, a second display element and/or further display elements in addition to the display element on which there is the current input focus may be displayed to the user. The displayed display elements do not necessarily need to be completely visible. The representation of a display element may include an icon. Additionally or alternatively, the representation of a display element may include a text. Finally, the representation of a display element may include a value. A plurality of display elements may be represented in a similar manner to a chain. In this case, a display element has at least one associated adjacent display element. Insofar as the first and last display elements are arranged adjacently to one another, each display element has at least two immediately adjacent display elements. The display elements may be arranged horizontally beside one another (“in a row”) in the representation of the plurality of display elements. Additionally or alternatively, the display elements may be arranged vertically above one another (“in a stack”) in the representation of the plurality of display elements. Finally, the display elements may be arranged one behind the other in the representation of the plurality of display elements. If multiple display elements are represented, they may conceal one another. It is better not to conceal the display element on which there is the input focus. A change of display position may result in the user gaining the visual impression that the display elements move horizontally (from left to right and/or from right to left) when the plurality of display elements are represented horizontally. If the plurality of display elements are represented vertically, a change of display position may result in the user gaining the visual impression that the display elements move vertically (from top to bottom and/or from bottom to top). If the plurality of display elements are represented one behind the other, a change of display position may result in the user gaining the visual impression that he is moving through the display elements in depth (in a direction going into the display and/or coming out of the display). In other words, the second user input having a second predefined operating force triggers the highlighting of a first display element. Ultimately, the possibility arises of having different display elements displayed and activated, or operated, using one and the same input device. This reduces the number or complexity of the input device(s)/operating elements.

In one possible development of the invention, it is additionally determined that the second user input having the second operating force has been performed for a predefined minimum length of time. In response to the second user input having the second operating force being determined as having been performed for a predefined minimum length of time, a second display element is selected from the plurality of display elements by selecting the input focus for the second display element. In other words, the input focus changes from the first display element to the second display element as a result. The predefined minimum length of time is preferably between 0.5 second and 2 seconds. The change of input focus from the first to the second display element, which is made on the basis of the performance of the second user input having the second operating force and for a predefined minimum length of time, allows the user to scroll (browse, move forward, flick through) through the display elements. The effect achieved by the scrolling is a gradual displacement of the partial representation of the plurality of display elements, which are not represented in full at the same time, with the input focus changing in each case. In other words, this variant development comprises a scroll function that is performed by maintaining an operating force.

In a further possible development of the invention, a third user input having a third predefined operating force acting on the input device is determined, which third operating force is higher than the second operating force. In response thereto, a second display element is selected from the plurality of display elements by changing the input focus to the second display element. The change of input focus from the first to the second display element, which is made on the basis of the increase in the operating force in relation to the second operating force, allows the user to scroll (browse, move forward, flick through) through the display elements. The effect achieved by the scrolling is a gradual displacement of the partial representation of the plurality of display elements, which are not represented in full at the same time, with the input focus changing in each case. In other words, this variant development comprises a scroll function that is performed by increasing an operating force.

The operating-force-sensitive input device may preferably be arranged on a steering wheel (multifunction steering wheel) of a transportation apparatus. Additionally or alternatively, the operating-force-sensitive input device may be integrated in a steering wheel (multifunction steering wheel) of a transportation apparatus. The input device may be arranged in particular on the right-hand and/or left-hand steering wheel spoke of a steering wheel. An arrangement on a steering wheel spoke of a transportation apparatus may be arranged in the region that is visible to the user, on the front of the steering wheel spoke, and/or in the region that is not visible to the user, on the rear of the steering wheel spoke. Additionally or alternatively, the input device may be arranged on the steering wheel rim of a transportation apparatus. An arrangement on the steering wheel rim of a transportation apparatus may be arranged in the region that is visible to the user, on the front of the steering wheel, and/or in the region that is not visible to the user, on the rear of the steering wheel. Finally, the operating-force-sensitive input device may be arranged in the region of a center console and/or an armrest.

A display element may represent in particular a function (vehicle function). Additionally or alternatively, a display element may display a status of a function and/or of the transportation apparatus. Finally, a display element may be configured to control/adjust a function (vehicle function). A vehicle function may be in particular a driver assistance function. In general, an electronic supplementary apparatus in a transportation apparatus that assists the user in various driving situations is described as a driver assistance function. Anti-lock braking system, traction control, attention assist, hill start assist, accelerate assist, brake assist, park assist, adaptive high-beam assist, cruise control, adaptive headlights, navigation system, emergency brake assist, lane departure warning system, road sign recognition, roll stability control, inter alia, are understood as driver assistance functions. Additionally or alternatively, a display element may represent a function of the infotainment system (media range). The infotainment system includes in particular radio, multimedia devices and connectivity functions. A status of a function or of the transportation apparatus that is displayed by way of a display element may be for example a fuel consumption, a journey time, a maximum range, etc. Accordingly, the display element represents the applicable status category. Adjusting a function comprises for example setting a speed limit for a cruise control. The example has no limiting nature for the invention but rather is merely intended to promote better comprehensibility and may be complemented by various other similar examples. Regardless of the vehicle function/status represented by a display element, the representation of a display element preferably refers to the represented function/status category. Accordingly, a display element may include an icon that represents the function linked with the display element. Additionally or alternatively, the representation of a display element may include a text that describes the function linked with the display element. Finally, the representation of a display element may include a current value that refers to a state of a function linked with the display element. An adjustability of a function may be represented by way of the display element.

In a further possible development of the invention, a confirmation from the user is received and, in response thereto, a function associated with the selected display element is activated. In other words, a function represented by the display element on which there is the input focus is activated after a confirmation from the user is received. The user may perform a confirmation by debouncing (releasing) the input device. Additionally or alternatively, the user may perform a confirmation by way of a voice input. Finally, the user may also perform a confirmation by way of a gesture, in particular a swipe gesture. The confirmation may be detected on the basis of the operating force acting on the operating-force-sensitive input device. Additionally or alternatively, the confirmation may be detected by way of an optical sensor, for example an interior camera. A function is activated in accordance with the respective specification of the function. By way of example, if a lane departure warning system is represented by the display element on which there is the input focus, a confirmation comprises activation (switching-on) of the lane departure warning system. Additionally or alternatively, deactivation (switching-off) of a function may accordingly be prompted by way of a confirmation from the user. Finally, parameter adjustment may also be prompted by way of a confirmation from the user. Accordingly, for example if an adaptive cruise control system were represented by the display element on which there is the input focus, a confirmation would prompt an increase in the desired minimum distance that is to be observed. The activation/deactivation/parameter adjustment may be reported to the user. A report of the activation/deactivation/parameter adjustment may be provided visually. A visual report of an activation/deactivation/parameter adjustment may be displayed in a display. Additionally or alternatively, a visual report of an activation/deactivation/parameter adjustment may influence a represented display element, for example by varying its representation, that is to say for example representing it in enlarged/reduced form, in brighter/darker form, or the like. Additionally or alternatively, a report of the activation/deactivation/parameter adjustment may be provided audibly. By way of example, an interior loudspeaker of the transportation apparatus may be used for audibly reporting an activation/deactivation/parameter adjustment. Finally, a report of the activation/deactivation/parameter adjustment may be provided by way of a haptic signal, for example a vibration.

The input focus may be changed in a predefined direction. If the plurality of display elements are represented horizontally, the predefined direction in which the change of input focus is made may be to the left. Additionally or alternatively, if the plurality of display elements are represented horizontally, the predefined direction in which the change of input focus is made may be to the right. If the plurality of display elements are represented vertically, the predefined direction in which the change of input focus is made may be upward. Additionally or alternatively, if the plurality of display elements are represented vertically, the predefined direction in which the change of input focus is made may be downward. If the plurality of display elements are represented one behind the other, the predefined direction in which the change of input focus is made may lead into the depth (into the display). Additionally or alternatively, if the plurality of display elements are represented one behind the other, the predefined direction in which the change of input focus is made may lead out of the depth (out of the display).

In one development of the invention, a fourth user input having a fourth predefined operating force acting on the input device may be determined, the fourth operating force being higher than the third operating force. In response thereto, a third display element is selected from the plurality of display elements by changing the input focus to the third display element, the third display element being arranged in the plurality of the plurality of display elements in a second direction, which has the opposite orientation to the first direction. Additionally or alternatively, the fourth operating force may be lower than the third operating force. In other words, the user may change the direction of scrolling through the display elements by changing the operating force: from scrolling to the left to scrolling to the right, or from scrolling to the right to scrolling to the left, or from scrolling upward to scrolling downward, or from scrolling downward to scrolling upward, or from scrolling to the rear to scrolling to the front, or from scrolling to the front to scrolling to the rear.

The first function may display in particular the plurality of display elements. In other words, the first function may be opening a menu. Additionally or alternatively, the first function may be display of a single display element. The display element may be displayed on a display. The display may be a part of the transportation apparatus that is also used for other functions, for example a head-up display and/or a multimedia display. The display may be arranged in the region behind the steering wheel. Additionally or alternatively, the display may be arranged in the region of the center console. The display element may additionally or alternatively be projected. The projection may be projected onto an element of the transportation apparatus, for example steering wheel, dashboard, door lining, which is preferably in the direct visual range of the user. Additionally or alternatively, the projection may be represented transparently on a window of the transportation apparatus.

A sensor (force sensor) may be used in order to determine the operating force acting on the input device. The force sensor may be in particular a spring-body force sensor. Additionally or alternatively, the force sensor may operate capacitively. Additionally or alternatively, a piezo force sensor may be used. Additionally or alternatively, a force sensor having oscillating elements may be used. Additionally or alternatively, an electrodynamic force sensor may be used. Finally, a resistive force sensor may also be used.

According to a second aspect of the present invention, a device that is configured to operate an operating-force-sensitive input device on a multifunction steering wheel for a transportation apparatus is proposed. Said device comprises a data input, an evaluation unit and a data output. In other words, the method according to an embodiment of the invention can be supported by an electronic control unit that uses further elements arranged in the transportation apparatus for the data input and the data output. According to an embodiment of the invention, the evaluation unit is configured to use the data input to determine a first user input having a first predefined operating force acting on the input device. In response to the determining and in conjunction with the data output, a first function is performed on the basis of the first operating force. In other words, the determining of a first predefined operating force acting on the operating-force-sensitive input device triggers a first function. Furthermore, the evaluation unit can also use the data input to determine a second user input having a second predefined operating force acting on the input device, the second operating force being higher than the first operating force. In response to the determining of the second operating force and in conjunction with the data output, a first display element is selected from a plurality of display elements displayed on a display unit by changing an input focus to the first display element. Accordingly, the device is configured to implement the features, feature combinations and advantages of the first-mentioned aspect of the invention, for which reason reference is made to the explanations above in order to avoid repetition.

According to a third aspect of the present invention, a transportation apparatus is proposed that comprises a device according to the second-mentioned aspect of the invention. The transportation apparatus may be in the form of a passenger car, transporter, truck, motorcycle, watercraft and/or aircraft. The device may be in a permanent and in particular distributed arrangement in the transportation apparatus and may be permanently integrated in the onboard power and information system of the transportation apparatus. In this way, the features, feature combinations and advantages are also obtained for the transportation apparatus in corresponding fashion.

Further details, features and advantages of the invention will emerge from the description that follows and the figures.

### BRIEF DESCRIPTION OF THE DRAWINGS

FIG. 1 shows a representation of an exemplary embodiment of a transportation apparatus with an exemplary embodiment of a device according to the invention for operating an operating-force-sensitive input device.

FIG. 2 shows an operating situation for a device according to an embodiment of the invention for operating an operating-force-sensitive input device.

FIG. 3 shows a representation of the determined operating force over time.

FIG. 4 shows a flowchart illustrating steps of an exemplary embodiment of a method according to the invention.

### DETAILED DESCRIPTION OF THE DRAWINGS

FIG. 1 shows a perspective view of a passenger car 1 according to an embodiment of the invention as an exemplary embodiment of a transportation apparatus with an exemplary embodiment of an operating-force-sensitive input device 2 on the right-hand steering wheel spoke 14 of a multifunction steering wheel 12. The display apparatus provided is a display 3 arranged behind the multifunction steering wheel 12. The index finger 13 of a user touches the operating-force-sensitive input device 2 according to an embodiment of the invention. The force acting on the operating-force-sensitive input device 2 is measured and transmitted to an electronic control unit 8, as an exemplary embodiment of an evaluation unit, via the data input 7. In response to the action of force on the touch-sensitive input device 2, display of the plurality of display elements 4, 5, 6 on the display 3 is selected as an exemplary embodiment of a first function and is sent to the display 3 via the data output 9. The display elements 4, 5, 6 each represent a different vehicle function. In this exemplary embodiment, the display elements 4, 5, 6 are represented one behind the other, with display element C 6 being partly concealed by display element B 5 and display element A 4, and display element B 5 being partly concealed by display element A 4. Display element A 4 is represented in a larger form than the display elements B 5 and C 6 as an exemplary embodiment of the visualization of the current input focus. By debouncing, that is to say removing, the index finger 13 from the touch-sensitive input device 2, the user of the touch-sensitive input device 2 activates the function represented by the display element on which there is the input focus. The activation of a function is confirmed to the user by way of an interior loudspeaker 11.

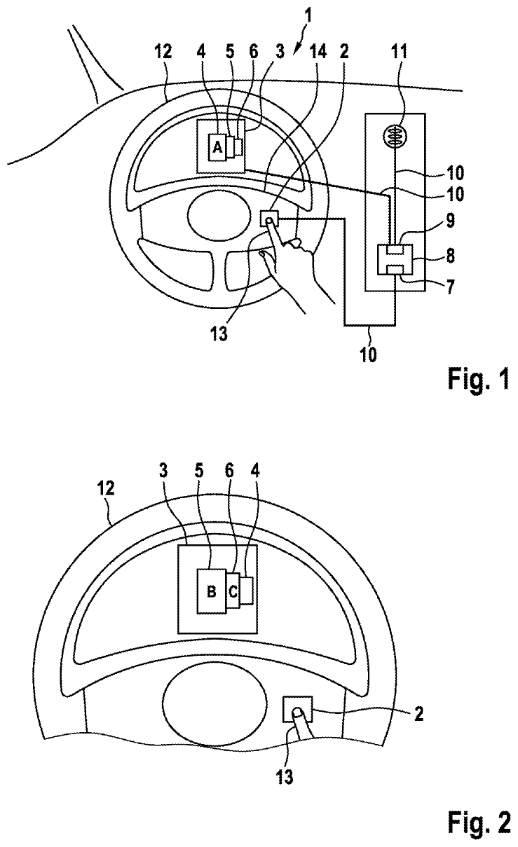

FIG. 2 shows the operating situation illustrated in FIG. 1 after an increase in the action of force by the user on the operating-force-sensitive input device 2. Accordingly, the input focus has transferred from the display element A 4 represented in FIG. 1 to the display element B 5, and the display element B 5 is accordingly displayed in the foreground and in a larger form and covers the display elements C 6 and A 4 in accordance with the order.

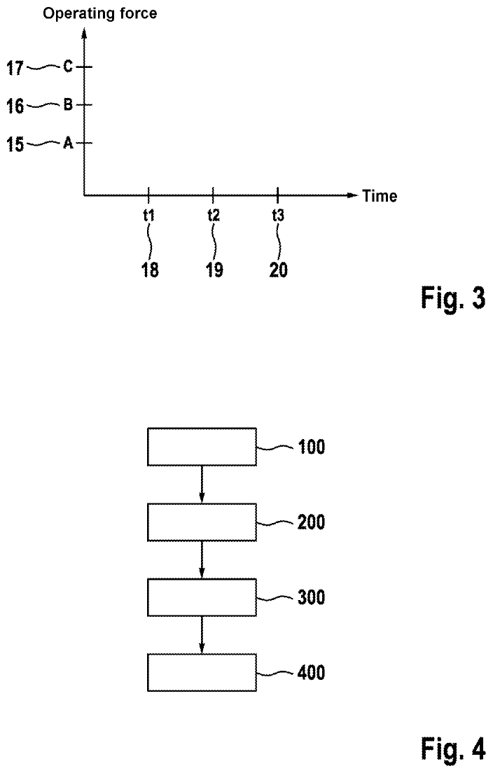

FIG. 3 shows a representation of the determined operating force over time. It depicts the position of the first determined operating force A 15 acting on the operating-force-sensitive input device 2 and the position of the second determined operating force B 16 acting on the operating-force-sensitive input device 2 and the position of the third determined operating force C 17 acting on the operating-force-sensitive input device 2 and also the time t1 18, the time t2 19 and the time t3 20. If t1 18=A 15, the plurality of display elements 4, 5, 6 are displayed in the display 3 as shown in FIG. 1. If t1=t2=A 15 or t1=A 15 and t2=B 16 or C 17, the input focus changes and the representation of the display elements 4, 5, 6 in the display is changed accordingly as shown in FIG. 2. If t2=B 16 and t3=A 15 or if t2=C 17 and t3=B 16 or A 15, the input focus changes and the representation of the display elements 4, 5, 6 in the display changes accordingly, in this example again as shown in FIG. 1.

FIG. 4 shows a flowchart containing steps of a method according to an embodiment of the invention for operating an operating-force-sensitive input device according to an embodiment of the invention in a transportation apparatus. In step 100, a first user input having a first predefined operating force acting on the input device is determined. In step 200, the determination leads to a first function being performed on the basis of the first operating force. Next, in step 300, a second user input having a second predefined operating force acting on the input device is determined. The second force is greater than the first force. In step 400, a first display element is selected from a plurality of display elements displayed on a display unit by changing an input focus to the first display element.

### LIST OF REFERENCE SIGNS

1 passenger car
2 operating-force-sensitive input device
3 display
4 display element A
5 display element B
6 display element C
7 data input
8 electronic control unit
9 data output
10 signal
11 interior loudspeaker
12 multifunction steering wheel
13 index finger
14 right-hand steering wheel spoke
15 operating force A
16 operating force B
17 operating force C
18 time t1
19 time t2
20 time t3

1.-11. (canceled)

12. A method for operating an operating-force-sensitive input device of a transportation apparatus, the method comprising:
automatically determining a first user input having a first predefined operating force acting on the input device,
automatically performing a first function based on the first operating force,
automatically determining a second user input having a second predefined operating force acting on the input device, wherein the second operating force is higher than the first operating force, and, in response thereto,
selecting a first display element from a plurality of display elements displayed on a display unit by changing an input focus to the first display element.

13. The method according to claim 12, further comprising:
automatically determining that the second user input having the second operating force has been performed for a predefined minimum length of time and, in response thereto,
selecting a second display element from the plurality of display elements by changing the input focus to the second display element.

14. The method according to claim 12, further comprising:
automatically determining a third user input having a third predefined operating force acting on the input device, wherein the third operating force is higher than the second operating force, and, in response thereto,
selecting a second display element from the plurality of display elements by changing the input focus to the second display element.

15. The method according to claim 12, wherein the input device is arranged on a multifunction steering wheel, or is integrated in the multifunction steering wheel.

16. The method according to claim 12, wherein each of the display elements represents a vehicle function.

17. The method according to claim 16, wherein the vehicle function is a driver assistance function.

18. The method according to claim 12, further comprising:
receiving a confirmation from a user and, in response thereto,
activating a function associated with the selected display element.

19. The method according to claim 12, wherein the input focus is changed in a first direction, and the method further comprises:
automatically determining a fourth user input having a fourth predefined operating force acting on the input device, wherein the fourth operating force is higher than the third operating force, and, in response thereto,
selecting a third display element from the plurality of display elements by changing the input focus to the third display element in a second direction, wherein the second direction has an opposite orientation with respect to the first direction.

20. The method according to claim 12, wherein the first function displays the plurality of display elements.

21. The method according to claim 12, wherein the operating force acting on the input device is determined by way of a sensor.

22. The method according to claim 21, wherein the sensor is a force sensor.

23. The method according to claim 21, wherein the sensor comprises at least one of:
a spring-body force sensor,
a piezo force sensor,
a force sensor having oscillating elements,
an electrodynamic force sensor, or
a resistive force sensor.

24. A device for operating an operating-force-sensitive input device on a multifunction steering wheel of a transportation apparatus, the device comprising:
a data input;
an evaluation unit; and
a data output;
wherein the evaluation unit is configured:
to use the data input to automatically determine a first user input having a first predefined operating force acting on the input device,
in conjunction with the data output, to automatically perform a first function based on the first operating force,
to use the data input to determine a second user input having a second predefined operating force acting on the input device, wherein the second operating force is higher than the first operating force, and
in conjunction with the data output, to select a first display element from a plurality of display elements displayed on a display unit by changing an input focus to the first display element.

25. A transportation apparatus comprising the device according to claim 24.
